(19) United States
(12) Patent Application Publication
(10) Pub. No.: US 2024/0330560 A1
(43) Pub. Date: Oct. 3, 2024

(54) Method And Device For Generating Integrated Circuit Layout

(71) Applicant: CELLIXSOFT CORPORATION, Beijing (CN)

(72) Inventors: Ke DING, Beijing (CN); Zhong DING, Beijing (CN); Chongxi ZHANG, Beijing (CN)

(73) Assignee: CELLIXSOFT CORPORATION, Beijing (CN)

(21) Appl. No.: 18/617,549

(22) Filed: Mar. 26, 2024

(30) Foreign Application Priority Data
Mar. 31, 2023 (CN) 202310342067.2

(51) Int. Cl. G06F 30/392; G06F 30/398

(52) U.S. Cl. CPC G06F 30/392; G06F 30/398

(57) ABSTRACT

A method and a device for generating an integrated circuit layout are provided. The method includes: acquiring feature information corresponding to multiple components in a first layout, and determining multiple components as target components respectively, the feature information at least includes a type, a size, a layer, and a position of each component; generating default patterns corresponding to the target components based on types of the target components; generating a featureless layout by using the feature information corresponding to the target components as parameter information of the default patterns; acquiring a process rule; based on the process rule, adjusting the parameter information of the default patterns to obtain an adjusted featureless layout; and obtaining a second layout, based on the adjusted featureless layout and the process rule.

### CROSS REFERENCE OF RELATED APPLICATION

This application claims priority to Chinese Patent Application No. 202310342067. 2, titled “METHOD AND DEVICE FOR GENERATING INTEGRATED CIRCUIT LAYOUT”, filed on Mar. 31, 2023 with the China National Intellectual Property Administration, which is incorporated herein by reference in its entirety.

### FIELD

The present disclosure relates to the technical field of integrated circuits, and in particular to a method and a device for generating an integrated circuit layout.

### BACKGROUND

Due to the ongoing advancements in science and technology, process optimization or process migration is constantly performed on integrated circuit layouts. In conventional technology, the process optimization or process migration is performed on an integrated circuit layout through manual adjustment, which is inefficient.

In addition, the manual adjustment of the integrated circuit layout has some disadvantages, such as inconvenient operation and poor usability.

### SUMMARY

In view of the above problems, a method and a device for generating an integrated circuit layout are provided according to the present disclosure.

A method for generating an integrated circuit layout is provided according to the present disclosure. The method includes: acquiring feature information corresponding to multiple components in a first layout, and determining the multiple components as target components respectively, where the feature information at least comprises a type, a size, a layer, and a position of each component; generating, based on types of the target components, default patterns corresponding to the target components; generating a featureless layout by using the feature information corresponding to the target components as parameter information of the default patterns; acquiring a process rule; adjusting, based on the process rule, the parameter information of the default patterns, to obtain an adjusted featureless layout; and obtaining, based on the adjusted featureless layout and the process rule, a second layout.

In an embodiment, the generating, based on the types of the target components, the default patterns corresponding to the target components, includes: in a case that the target component is a metal wire, generating a geometric line corresponding to the metal wire; in a case that the target component is a circuit unit, generating a geometric rectangle corresponding to the circuit unit; and in a case that the target component is a via, generating a geometric point corresponding to the via.

In an embodiment, in a case that the target component is the circuit unit, the method further includes: generating a point corresponding to a port of the circuit unit in the featureless layout; and generating a geometric dashed line in the featureless layout, where the geometric dashed line corresponds to a connecting line between the port of the circuit unit and a metal wire outside the circuit unit.

In an embodiment, the process rule includes a first process rule, a second process rule and an optimization rule.

In an embodiment, the method for generating an integrated circuit layout further includes: acquiring a ratio of a minimum size of each target component in the first process rule to an actual size of an actual component corresponding to each target component in the first layout; and obtaining the second layout, based on the ratio, the adjusted featureless layout and the second process rule.

In an embodiment, the method for generating an integrated circuit layout further includes: acquiring a ratio of the size of each target component to a size of an adjacent component in the first process rule; and obtaining the second layout, based on the ratio, the adjusted featureless layout and the second process rule.

In an embodiment, the optimization rule includes: mapping information of a circuit unit.

In an embodiment, the feature information further includes a connection mode identifier, which is used for identifying a connection mode between the target components; and the adjusting, based on the process rule, the parameter information of the default patterns, to obtain an adjusted featureless layout includes: adjusting, based on the connection mode identifier between target components in the process rule, a connection mode between default patterns in the featureless layout to obtain the adjusted featureless layout.

In an embodiment, the method for generating an integrated circuit layout further includes: based on the mapping information of the circuit unit, acquiring, in the process rule, components corresponding to the target components; in generation of the second layout, mapping components in the second layout generated based on the default patterns corresponding to the target components as the components corresponding to the target components; and determining, based on the parameter information of the default patterns in the adjusted featureless layout, feature information of the components corresponding to the target components in the second layout.

A device for generating an integrated circuit layout is further provided according to the present disclosure. The device includes: a feature information acquisition device, configured to acquire feature information corresponding to multiple components in a first layout and determine the multiple components as target components respectively, where the feature information at least includes a type, a size, a layer, and a position of each component; a default pattern generation device, configured to generate default patterns corresponding to the target components based on types of the target components; a featureless layout generation device, configured to generate a featureless layout by using the feature information corresponding to the target components as parameter information of the default patterns; a process rule acquisition device, configured to acquire a process rule; a featureless layout adjustment device, configured to adjust the parameter information of the default patterns based on the process rule to obtain an adjusted featureless layout; and a second layout generation device, configured to obtain a second layout based on the adjusted featureless layout and the process rule.

A device for generating an integrated circuit layout is further provided according to the present disclosure. The device includes a memory having a computer program stored thereon; and a processor; where the processor, when executing the computer program, is configured to implement the above method for generating an integrated circuit layout.

A non-transitory computer readable storage medium is further provided according to the present disclosure. The non-transitory computer readable storage medium stores a computer program thereon, where the computer program, when executed by a processor, implements the above method for generating an integrated circuit layout.

### BRIEF DESCRIPTION OF THE DRAWINGS

In order to more clearly describe the technical solutions in the embodiments of the present disclosure or the technical solutions in the conventional technology, drawings to be used in the description of the embodiments or the conventional technology are briefly described hereinafter. It is apparent that the drawings described below are merely used for describing the embodiments of the present disclosure, and those skilled in the art can obtain other drawings based on the provided drawings without any creative effort.

FIG. 1 is a flowchart of a method for generating an integrated circuit layout according to the present disclosure;

FIG. 2 is a flowchart of a method for performing process optimization or process migration using a featureless layout according to the present disclosure;

FIG. 3(a) is an integrated circuit layout;

FIG. 3(b) is a featureless layout corresponding to the integrated circuit layout in FIG. 3(a);

FIG. 3(c) is an integrated circuit layout obtained by performing process optimization or process migration on the integrated circuit layout in FIG. 3(a);

FIG. 4(a) is an integrated circuit layout;

FIG. 4(b) is a featureless layout corresponding to the integrated circuit layout in FIG. 4(a);

FIG. 4(c) is an integrated circuit layout obtained by performing process optimization or process migration on the integrated circuit layout in FIG. 4(a);

FIG. 5 is a flowchart of a method for performing process optimization or process migration using a featureless layout according to the present disclosure;

FIG. 6(a) is a circuit unit in an integrated circuit;

FIG. 6(b) is an integrated circuit layout;

FIG. 7 is a featureless layout corresponding to the integrated circuit layout in FIG. 6(b);

FIG. 8 is a mapping circuit unit corresponding to the circuit unit in FIG. 6(a);

FIG. 9(a) is an integrated circuit layout obtained by performing process optimization or process migration on the integrated circuit layout in FIG. 6(b);

FIG. 9(b) is an integrated circuit layout obtained by performing process optimization or process migration on the integrated circuit layout in FIG. 6(b);

FIG. 10 shows information corresponding to a port;

FIG. 11(a) is an integrated circuit layout;

FIG. 11(b) shows a featureless layout corresponding to the integrated circuit layout in FIG. 11(a);

FIG. 12 is an integrated circuit layout obtained by performing process optimization or process migration on the integrated circuit layout in FIG. 11(a); and

FIG. 13 is a schematic structural diagram of a device for generating an integrated circuit layout according to the present disclosure.

### DETAILED DESCRIPTION OF EMBODIMENTS

As described above, in the conventional technology, the process optimization or the process migration performed on a first layout is usually through manual adjustment by an engineer. Generally, the engineer adjusts size parameters of the components in the first layout according to a process optimization rule or a process migration rule and then adjusts positions of the components to solve a potential verification problem after the adjustment of the size parameters. In addition, a connection mode may be required to be changed or mapping may be required to be performed on some circuit units.

However, in the conventional technology, the process migration or the process optimization is performed on the first layout through manual adjustment, which has poor usability and is inefficient.

In order to make those skilled in the art better understand the solutions according to the present disclosure, technical solutions of the embodiments of the present disclosure are described clearly and thoroughly below in conjunction with the drawings of the embodiments of the present disclosure. Apparently, the embodiments described below are only some embodiments of the present disclosure, rather than all the embodiments. Any other embodiments obtained by those skilled in the art based on the embodiments in the present disclosure without any creative effort fall within the protection scope of the present disclosure.

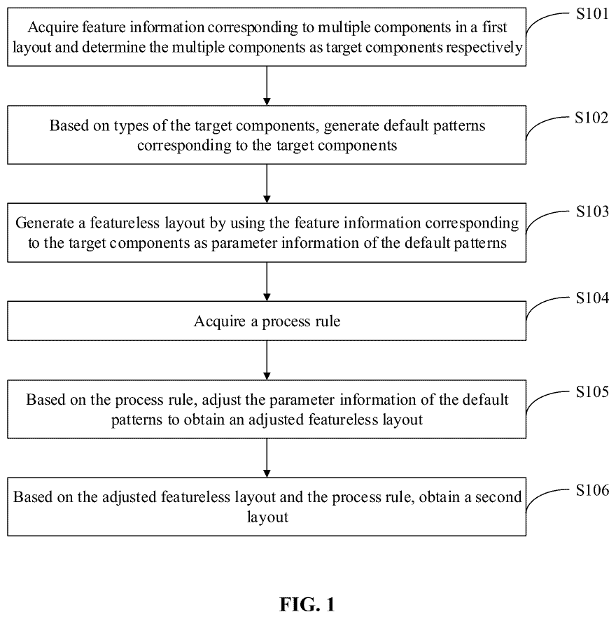

FIG. 1 is a flowchart of a method for generating an integrated circuit layout according to an embodiment of the present disclosure. The method includes steps S101 to S106 as follows.

In step S101, feature information corresponding to multiple components in a first layout is acquired, and the multiple components are determined as target components respectively.

The integrated circuit layout is a description of physical conditions of a real integrated circuit in plane geometry. The first layout refers to the integrated circuit layout.

Where, the feature information corresponding to a component refers to all feature information, of the component, existing in the first layout. For example, a layer of the component, a size of the component, a type of the component, position information of the component, a connection mode identifier of the component, and the like.

In step S102, default patterns corresponding to target components are generated by using types of the target components.

For each target component, after obtaining the type of the target component, the default pattern corresponding to the target component is generated. The default pattern may be set artificially. In a case that the target component is a metal wire, a geometric line may be generated to correspond to the metal wire. Alternatively, a dashed line or a curved line may be generated to correspond to the metal wire. The featureless form of the metal wire is determined based on the default pattern. In a case that the target component is a via, a geometric point or other geometry may be generated to correspond to the via. The featureless form of the via is determined based on the default pattern. In a case that the target component is a circuit unit, a geometric rectangle may be generated to correspond to the circuit unit. The featureless form of the circuit unit is determined based on the default pattern.

In step S103, a featureless layout is generated by using the feature information corresponding to the target components as parameter information of the default patterns.

Where, in the generation of the featureless layout, position information and layer information corresponding to the target components are used as position information and layer information of the default patterns. The default patterns are generated in the featureless layout. Positions of the default patterns in the featureless layout may be determined based on absolute positions of the target components in the first layout. Alternatively, the position information of the default patterns may be obtained by scaling the position information of the target components to a certain scale, and the default patterns are located at relative positions after the scaling.

In an embodiment, the target component is a metal wire in the first layout. Feature information of the metal wire in the first layout includes: the layer of the metal wire, the coordinates of the metal wire, the type of the metal wire, the connection relationship between the metal wire and adjacent component(s), and the width of the metal wire. When generating the featureless layout, a geometric line is generated to correspond to the metal wire, and the generated geometric line is located in a corresponding layer of the featureless layout. In a case that the metal wire is located in a first layer of the first layout, the geometric line is located in a first layer of the featureless layout. The layer size of featureless layout may be the same as or different from the first layout. In a case that the size of the first layer of the first layout is 100*100, the size of that of the featureless layout may be 100*100, 10*10, or any other size. In a case that the size of the first layer of the first layout is 100*100 and a midpoint of the metal wire is located at a position with coordinates of (10,10) in the first layer of the first layout, the size of the first layer of the generated featureless layout may also be 100*100 and a midpoint of the geometric line is located at a position with coordinates of (10,10) in the first layer of the featureless layout. In a case that the size of the first layer of the generated featureless layout is 10*10, the coordinates may be scaled proportionally to (1,1), and the midpoint of the geometric line is located at a position with coordinates of (1,1) in the first layer of the featureless layout. After the generation of the geometric line, the information of the metal wire such as the width of the metal wire, the length of the metal wire and the connection mode of the metal wire are provided to the geometric line in a form of parameters. The geometric lines may be thin lines with a negligible width. Alternatively, the geometric line may be thin lines that are located in different layers and the same in width. Alternatively, the geometric line may be thin lines that are located in a same layer and the same in width. Alternatively, the geometric lines may be thin lines that are located in different layers and different in width. The geometric point may be a determined pattern, such as a circle and a square in a constant size. Alternatively, the geometric point may be a determined pattern in a constant size according to a layer.

In a case that the target component is a circuit unit in the first layout, in the featureless layout, a geometric rectangle may be generated at a position corresponding to a position of the target component in the first layout. Alternatively, the geometric rectangle may be generated at a proportionally scaled position corresponding to a position of the target component in the first layout, and the feature information corresponding to the circuit unit is provided to the geometric rectangle in a form of parameters.

In step S104, a process rule is acquired.

Where, the process rule may include a first process rule, a second process rule and an optimization rule. The first process rule is a process rule for the first layout. The second process rule may be a target process rule to migrate the first layout to a new process. The optimization rule may be used to optimize the first layout. The optimization rule may include connection mode identifier(s) and mapping information for circuit unit(s). Alternatively, the optimization rule may include the connection mode identifier(s) or the mapping information for circuit unit(s). Alternatively, the optimization rule may include neither the connection mode identifier(s) nor the mapping information for circuit unit(s).

In step S105, the parameter information of the default patterns is adjusted based on the process rule to obtain an adjusted featureless layout.

In an embodiment, the parameter information of the default patterns in the featureless layout is adjusted. For example, for a geometric line in the featureless layout, the width of the geometric line is 0.3. Based on the second process rule or the optimization rule, a width of the metal wire corresponding to the geometric line in the second layout may be obtained as 0.2. Then the width of the geometric line in the featureless layout may be adjusted from 0.3 to 0.2.

In step S106, a second layout is obtained based on the adjusted featureless layout and the process rule.

The parameter information of the default patterns in the adjusted featureless layout corresponds to parameter information of components in the second layout. The second layout is obtained based on the adjusted featureless layout and the process rule. In an embodiment, the metal wire is described as an example. In this case, the width of the geometric line in the adjusted featureless layout is 0.2. And the geometric line, in the featureless layout, further has parameters such as the layer information and position information. When generating the second layout, based on the second process rule, a metal wire corresponding to the geometric line is generated in a corresponding layer. For example, in a case that the geometric line is located in the first layer of the featureless layout, the metal wire is generated in a first layer of the second layout. The width and the position of the metal wire are generated based on the parameter information of the geometric line in the adjusted featureless layout. For example, in a case that the width of the geometric line in the adjusted featureless layout is 0.2, the width of the metal wire generated in the second layout is 0.2.

The featureless layout obtained with the above method can accurately identify the size information and the position information of the components in the first layout. Different default patterns are generated corresponding to different types of components. The default patterns in the method may be set, which has strong extensibility. The featureless layout generated with the method according to the present disclosure has excellent usability and efficiency in some scenarios.

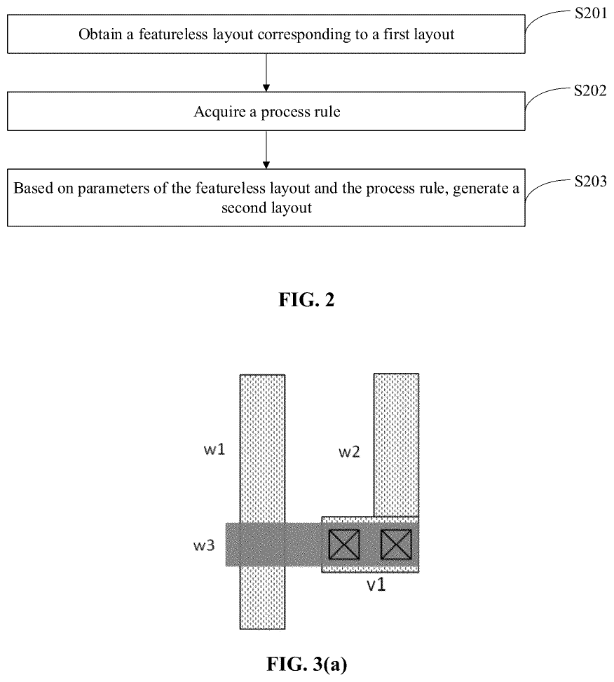

After obtaining the featureless layout, process optimization or process migration may be performed using the featureless layout. FIG. 2 is a flowchart of a method for performing process optimization or process migration using a featureless layout. The method includes steps S201 to S203 as follows.

In step S201, a featureless layout corresponding to a first layout is obtained.

Where, the featureless layout corresponding to the first layout is generated by using the method shown in FIG. 1.

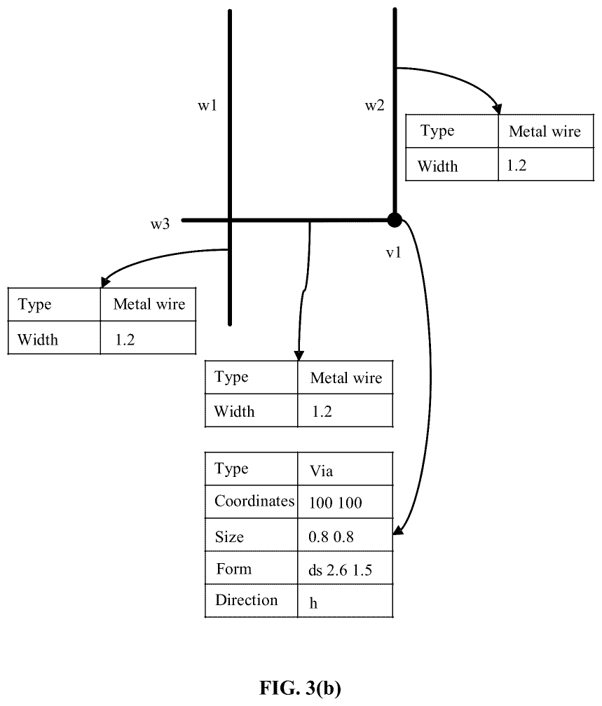

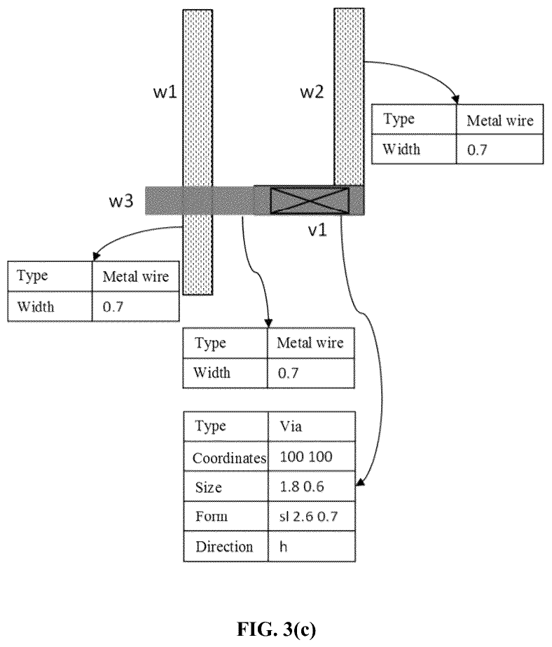

To better illustrate the processing of the metal wire and the via, a first layout is shown in FIG. 3(a) as an example. Apparently, other first layout provided with a metal wire and a via shall fall within the protection scope of the present disclosure. In different first layouts, the processing of the metal wire and the via may be the same.

Where, as shown in FIG. 3(a), the first layout includes two layers of metal wires and one layer of a via. w1 and w2 are located in a same layer. For metal wires in a same layer, connection between the metal wires requires overlap between patterns of the metal wires. Therefore, there is no connection between w1 and w2. The layer where w1 and w2 are located is different from a layer where w3 is located. For metal wires in different layers, connection between the metal wires requires overlap between patterns of the metal wires and a via at the overlap. Therefore, there is no connection between w1 and w3, and w2 and w3 are connected to each other through a via v1.

Where, the default pattern of the metal wire is a geometric line, and the default pattern of the via is a point. The three metal wires w1, w2 and w3 in the first layout correspond to three geometric lines in the featureless layout respectively. A positional relationship among the three geometric lines is related to the positional relationship among w1, w2 and w3. w2 and w3 are connected to each other through a metal via in the first layout. In the featureless layout, the connection between w2 and w3 is represented in a form of connecting two lines through a geometric point.

Where, the feature information of the default patterns in the featureless layout is the same as the feature information of the target components. The default patterns have size parameter information, position information, and the like. In addition, the default patterns may further include other information, such as the types of the components in the first layout, the direction of placement, the layer information, the quantity of vias, and shapes of the vias.

FIG. 3(b) illustrates four tables, where four components point to their respective tables through four arrow lines. The table to which w1 points includes “type” and “width”, where “type” indicates that a type of the component w1 is a metal wire and “width” indicates that a width of the metal wire w1 is 1.2 μm. The table to which w2 points and the table to which w3 points respectively include a same type of information as the table to which w1 points, which will not be repeated here. The table to which v1 points includes “type”, “coordinates”, “size”, “form”, and “direction”, where “type” indicates that a type of the component v1 is a via, “coordinates 100, 100” indicates that coordinates of v1 in the first layout is (100, 100), and “size 0.8 0.8” indicates that a length and a width of the via are both 0.8 μm. In “form ds2.6 1.5”, “ds” indicates that there are two square vias, and “2.6 1.5” indicates that a length and a width of covering pattern of vias are 2.6 μm and 1.5 μm respectively. The covering pattern of vias refers to a pattern corresponding to an overlapping region between the portion where the vias located at the w2 and the portion where the vias located at the w3. Direction “h” indicates that the vias are placed in a horizontal direction. In a case that the column of “direction” is filled with “v”, it indicates that the vias are placed in a vertical direction.

It should be noted that only the names of the parameters and the form in which the parameters are represented used in FIG. 3(b) are described here, and the parameters may be represented in another form in other scenarios. For example, the parameters are represented in a form of texts rather than tables. For another example, the letters used to represent the parameters are replaced. Alternatively, the components in the first layout are represented in other form. All the alternatives should fall within the protection scope of the present disclosure.

In step S202, a process rule is acquired.

Where, the process rule may include a first process rule, a second process rule and an optimization rule. The first process rule is a process rule for the first layout. The optimization rule may be an optimization rule to optimize the first layout. The second process rule may be a target process rule to migrate the first layout to a new process.

In step S203, based on parameters of the featureless layout and the process rule, a second layout is generated.

For example, the widths of the metal wires corresponding to the three geometric lines in the featureless layout in FIG. 3(b) are 1.2 μm, and there are two square vias in the featureless layout. Each via has a length of 0.8 μm and a width of 0.8 μm, and the covering pattern of the vias has a length of 2.6 μm and a width of 1.5 μm.

The feature information of the target components and the first process rule are acquired.

For example, in the first process rule, a minimum width of a metal wire is 1.2 μm. A ratio of the width of the metal wires w1, w2, and w3 to the minimum width in the first process rule is determined in conjunction with the acquired feature information of the target components and the first process rule. The second process rule specifies that a minimum width of a metal wire is 0.7 μm, a via is in a form of a rectangle via, the via has a length of 1.8 μm and a width of 0.6 μm, and a covering pattern of the via has a length of 2.6 μm and a width of 0.7 μm.

Under an optimization principle, the minimum width in the first process rule corresponds to the minimum width in the second process rule. Since the ratio of the width of the metal wires w1, w2, and w3 to the minimum width in the first process rule is 1:1, parameters in FIG. 3(c) are generated based on the second process rule. Numbers corresponding to “width” in the tables to which w1, w2 and w3 respectively point are all adjusted to the minimum width “0.7”. Content corresponding to “form” in the table to which v1 points is adjusted to “sl 2.60.7”, content corresponding to “size” in the table to which v1 points is adjusted to “1.80.6”. Features of the components are updated with the adjusted parameters to generate a second layout as shown in FIG. 3(c). In the second layout shown in FIG. 3(c), the widths of the three wires w1, w2 and w3 are all 0.7 μm, the via v1 is in a form of a rectangle via, the covering pattern of the via has a length of 2.6 μm and a width of 0.7 μm, the size of the via is a length of 1.8 μm and a width of 0.6 μm, and a direction of the via is “h”, indicating that the via is placed in a horizontal direction.

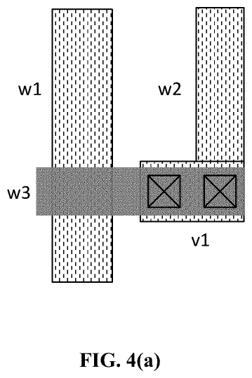

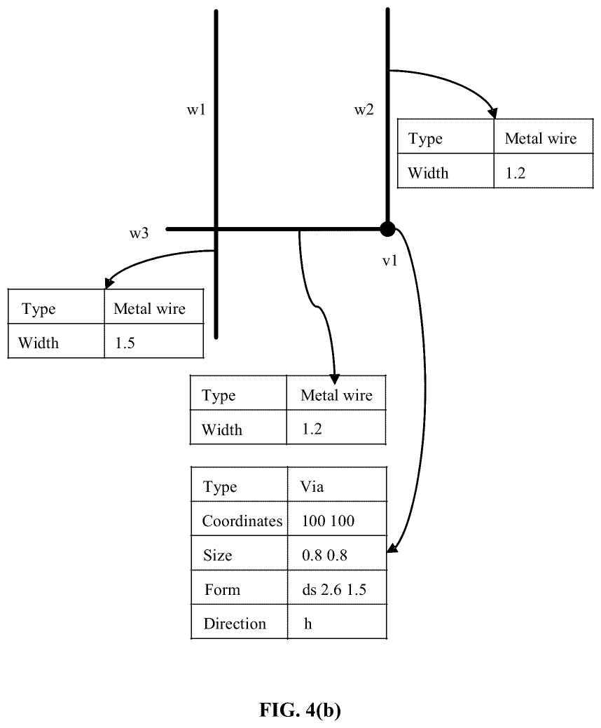

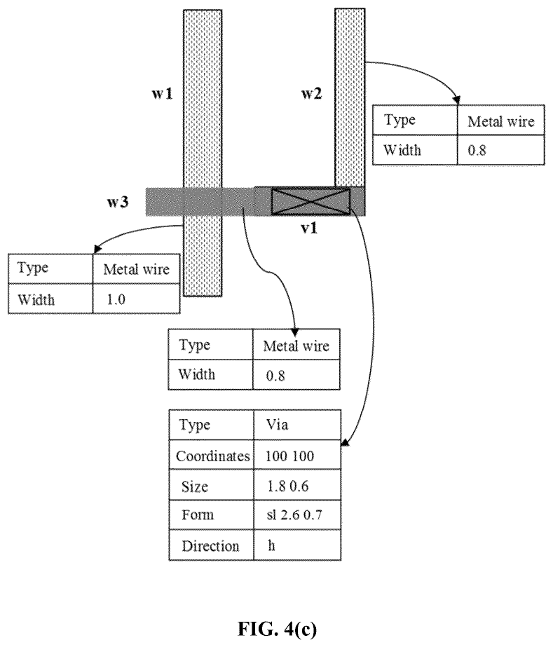

Hereinafter, as an example, the first layout is shown in FIG. 4(a). Apparently, all other first layouts with metal wires and vias fall within the protection scope of the present disclosure. For different first layouts, the processing manner of the metal wires and vias may be the same.

FIG. 4(a) is different from FIG. 3(a) only in the widths of the three wires.

In FIG. 4(b), three arrow lines are used to point to the feature information of the metal wires corresponding to the geometric lines respectively, and one arrow line is used to point to the feature information of the via corresponding to the geometric point. The table to which w1 points is described in detail hereinafter. In this table, content corresponding to “type” is “metal wire”, and a width of the metal wire is 1.5 μm. Since the table to which w2 points and the table to which w3 points are similar to the table to which w1 points in content, contents of the table to which w2 points and the table to which w3 points are not repeated here. The table to which v1 in FIG. 4(c) points is the same as the table to which v1 in FIG. 3(c) points in content, and details are with reference to the above descriptions.

A ratio of the target component to an adjacent component is acquired.

Under another optimization principle, the second layout is generated based on the ratio of the target component to the adjacent component and the second process rule.

In the first layout shown in FIG. 4(a), the metal wire w1 and the metal wire w2 located in a same layer are different in width, and a ratio is w1:w2=1.5:1.2=5:4. The minimum width of a metal wire specified in the second process rule is acquired as 0.8 μm. Although the width of the metal wire w1 in the featureless layout shown in FIG. 4(b) may be adjusted to 0.8 μm to generate the second layout, without resulting in a verification problem such as DRC, such adjustment does not adequately reflect the inherent design features of the first layout in FIG. 4(a). Especially when w1 is a key signal line such as a power line and a clock line, an increase of the width is conducive to improving performance. Therefore, in the present disclosure, the inherent design features of the first layout and the second process rule are comprehensively considered, and the width of w1 is finally optimized to 1 um based on the ratio of w1:w2=1.5:1.2=5:4.

Under an optimization principle, the second layout is generated, based on an area of the target component or a ratio of a length to a width of the target component and the second process rule. In the following description, the second layout is generated based on the ratio of the length to the width of the target component as an example. In FIG. 3(a), w2 and w3 are connected through vias, i.e., in a form of two square vias. A ratio of a length to a width of the covering pattern for the vias is 2.6:1.5, i.e., the value corresponding to the parameter form. While generating the via of the second layout shown in FIG. 3(c), i.e., the via through which w2 and w3 are connected, a via is selected from the vias specified in the second process rule. Where, the selected via has a length-to-width ratio in its covering pattern that is closest to 2.6:1.5. And the selected via is placed at the position as shown in FIG. 3(c), a via has a length-to-width ratio in its covering pattern of 2.6:0.7 is generated, and the via is in a form of one rectangle via.

The parameters in the featureless layout generated with the method according to the present disclosure can be adjusted based on the process rule in the scenarios of process optimization and process migration, and the second layout can be generated by using the adjusted parameters. In this way, the efficiency is improved compared with the conventional technology. The adjustment is performed by using the parameters calculated based on the size parameters in the featureless layout and the constraint information in the process rules, which leads to a better process optimization result or process migration result.

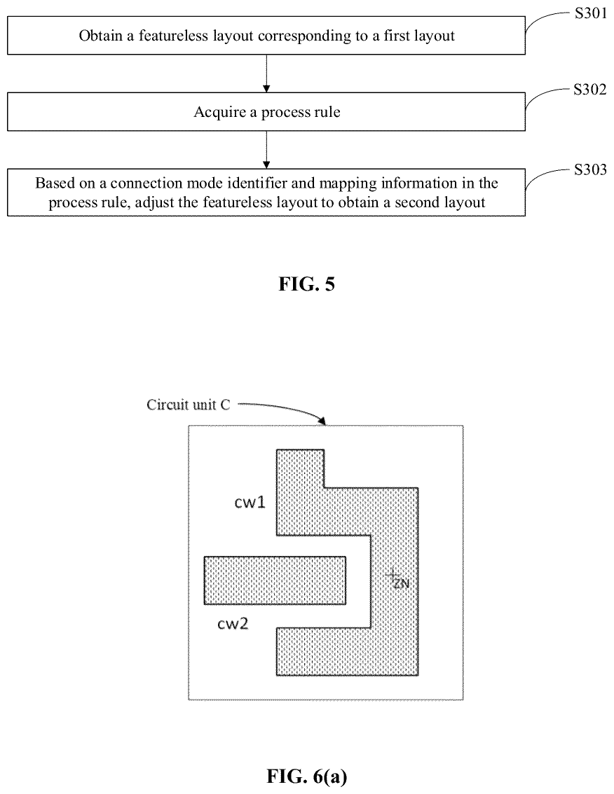

In the process of process optimization or process migration, it is required to process the connection relationship, and it may further be required to perform mapping generation on a circuit unit. FIG. 5 is a flowchart of a method for performing process optimization or process migration using a featureless layout according to another embodiment of the present disclosure. The method includes the following steps S301 to S303.

In step S301, a featureless layout corresponding to a first layout is acquired.

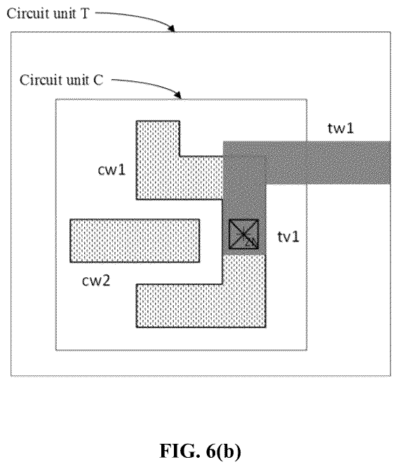

As an example, a first layout is shown in FIG. 6(b), which better illustrates the processing on metal wires and circuit units in different layers in the first layout. Apparently, other integrated circuit layouts with connection relationship fall within the protection scope of the present disclosure. For different first layouts, the processing manner of the metal wires and circuit units may be the same.

A circuit unit in the integrated circuit layout may be provided with a port, through which the circuit unit is connected to a metal wire. The port may have a text annotation. The text annotation is used to indicate a position of the port and a name of the port. The port of the circuit unit is in a shape of a polygon or a rectangle.

In addition to interconnection information of metal wire(s) and via(s), a layout may further include interconnection information of circuit unit(s) and metal wire(s). The interconnection between circuit unit(s) and metal wire(s) may include two parts, one part of the metal wire is inside the circuit unit, and the other part of the metal wire is outside the circuit unit.

FIG. 6(a) shows a circuit unit C including two metal wires cw1 and cw2 that are located in a same layer M1. Where, cw1 and cw2 are located inside the circuit unit. A cross in the FIG. 6(a) denotes a position of a port of the circuit unit C, and ZN denotes a text annotation of the port. FIG. 6(b) shows a connection mode of the circuit unit C in a circuit unit T of the layout. Where, tw1 is a metal wire located in a layer M2. The circuit unit T of the layout further includes a via tv1 located in a layer V1, and cw1 inside the circuit unit C is connected to the metal wire tw1 through the via tv1.

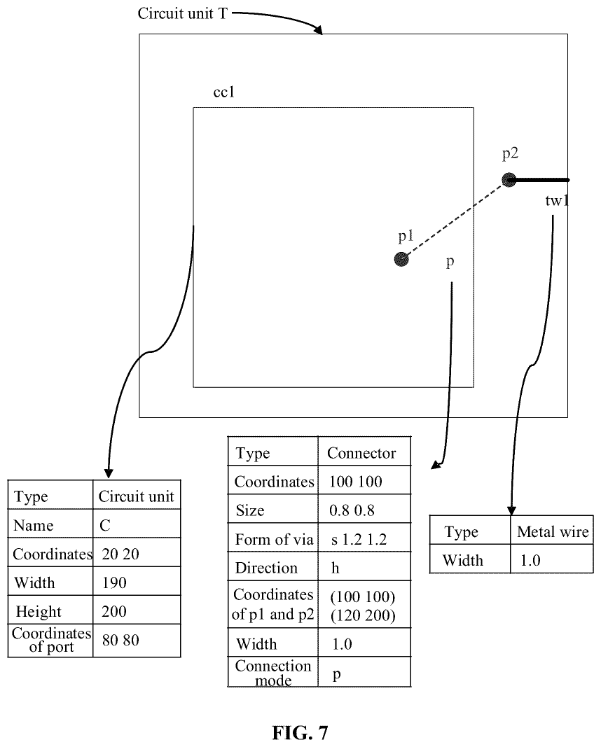

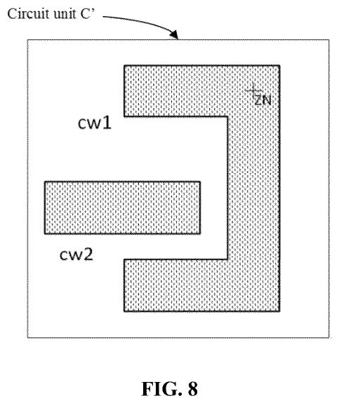

In this case, a featureless geometric rectangle cc1 is generated based on the circuit unit C, as shown in FIG. 7. The geometric rectangle includes a position of the port ZN. The port may correspond to a geometric point p1 as shown in FIG. 7 inside cc1. The part of tw1 connected to the inside of the circuit unit C corresponds to a dashed line as shown in the FIG. 7. The other part of tw1 located at the outside of the circuit unit C corresponds to the form as shown in FIG. 7. p2 denotes an external connection point between tw1 and the circuit unit C. And p2 may be located on a boundary of the circuit unit C or at a position with a specified distance from the boundary of the circuit unit C. As an example, p2 is located at a position with a specified distance from the boundary of the circuit unit C.

As shown in FIG. 7, cc1 in the featureless layout corresponds to the circuit unit C in the first layout as shown in FIG. 6(b), and parameters of cc1 correspond to the parameters of the circuit unit C. In a table to which cc1 points, content corresponding to “type” indicates that a component type of the circuit unit C is “circuit unit”, content corresponding to “name” indicates that a name of the circuit unit is “C”, content corresponding to “coordinates” indicates that coordinates of top point of the circuit unit C are (20,20), content corresponding to “width” indicates that a width of the circuit unit C is 190 μm, content corresponding to “height” indicates that a height of the circuit unit C is 200 μm, and content corresponding to “coordinates of port” indicates that coordinates of the position of the port ZN of the circuit unit C are (80,80). “p” represents the connection between the port ZN of the circuit unit C and the metal wire tw1 in the circuit unit T in the first layout. In other words, the connection includes the via tv1 and a part of the metal wire tw1. “p” has corresponding parameters. In a table to which “p” points, content corresponding to “type” indicates that a component type is “connector”, content corresponding to “coordinates” indicates that coordinates of the via tv1 are (100, 100), and content corresponding to “size” indicates that the via tv1 has a length of 0.8 μm and a width of 0.8 μm. In “s 1.2 1.2” corresponding to the form of via, “s” indicates that the via is in a form of a single square via, “1.2 1.2” indicates that a covering pattern of the via has a length of 1.2 μm and a width of 1.2 μm, content corresponding to “direction” indicates that the via tv1 is placed in a horizontal direction, content corresponding to “coordinates of p1 and p2” indicates that coordinates of p1 are (100, 100) and coordinates of p2 are (120, 200), content corresponding to “width” indicates that the width of the metal wire tw1 is 1.0 μm, and the connection mode identifier “p” indicates that the via tv1 through which cc1 and the metal wire tw1 are connected is located above the metal wire cw1 inside cc1. The external connection wire tw1 corresponds to a part of tw1 in the first layout and has corresponding parameters. In a table to which tw1 points, content corresponding to “type” indicates that a component type is “metal wire”, and content corresponding to “width” indicates that the width of the metal wire tw1 is 1.0 μm.

In step S302, a process rule is acquired.

Where, the process rule may include a first process rule, a second process rule and an optimization rule. The first process rule is a process rule for the first layout. The second process rule may be a target process rule to migrate the first layout to a new process. The optimization rule may be used to optimize the first layout. The optimization rule may include a connection mode identifier and circuit unit mapping information. Alternatively, the optimization rule may include the connection mode identifier or the circuit unit mapping information. Alternatively, the optimization rule may include neither the connection mode identifier nor the circuit unit mapping information. As an example, the optimization rule includes the connection mode identifier and the circuit unit mapping information.

In step S303, based on a connection mode identifier and mapping information in the process rule, the featureless layout is adjusted to obtain a second layout.

Where, the process rule may specify that a circuit unit is subjected to mapping generation. Apparently, the circuit unit may not be subjected to mapping generation. Hereinafter, an example is provided for illustration, where a circuit unit is subjected to mapping generation.

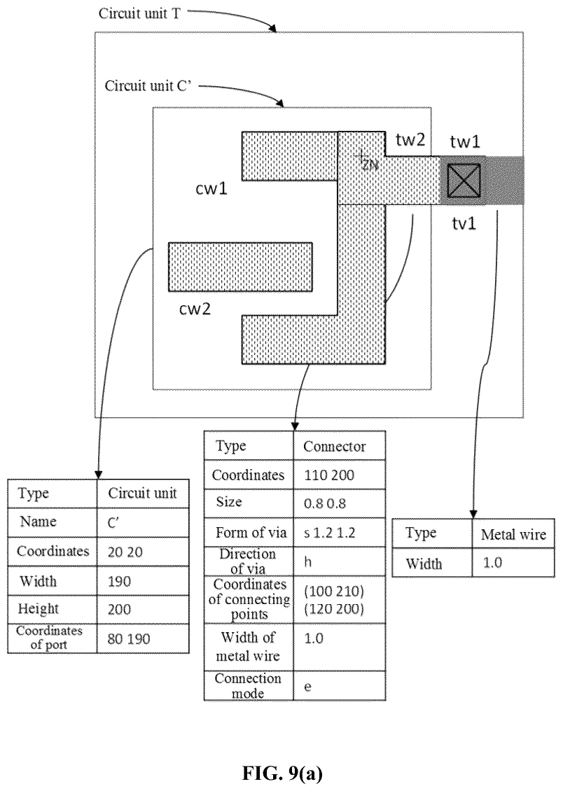

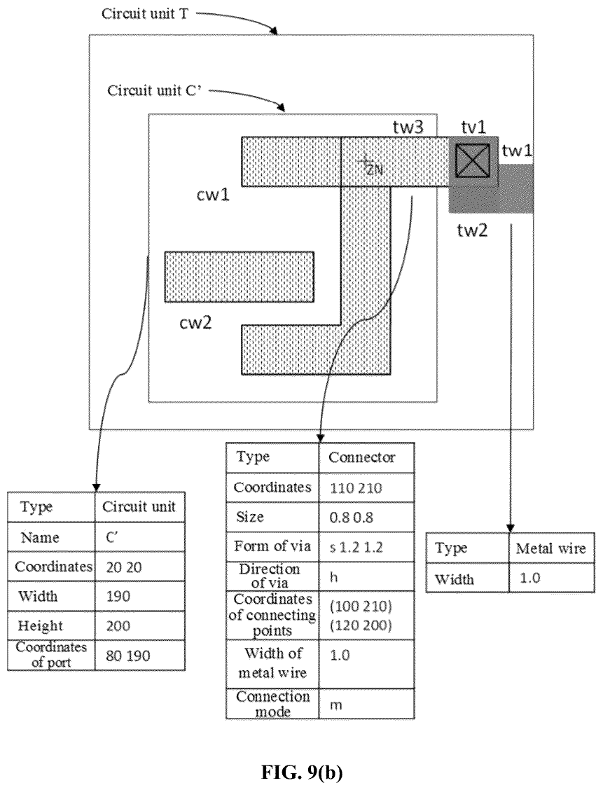

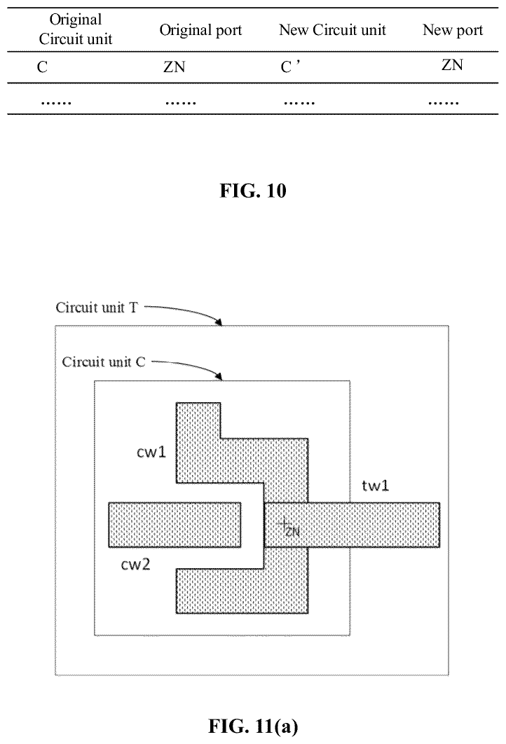

The process rule includes a circuit unit C′ corresponding to the circuit unit C. The process rule specifies that the circuit unit C in the first layout is mapped to a form of the circuit unit C′ shown in FIG. 8. Mapping information is as shown in FIG. 10. A layout of the circuit unit C′ is as shown in FIG. 8. The layout includes two metal wires cw1 and cw2 that are located in a layer M1. A cross on cw1 denotes a position of a port, and ZN denotes a text annotation of the port.

Where, a connection mode identifier “e” is specified in the process rule, and thus the connection mode identifier “p” in the featureless layout is changed to “e”. In the connection mode indicated by “e”, the via is placed at an endpoint of the metal wire. In this case, the via tv1 is generated at a left endpoint of tw1, and tw2 is generated in the layer M1 to connect the port ZN on cw1 inside the circuit unit C′ to tv1. As shown in FIG. 9(a), a second layout is generated based on the featureless layout with a connection mode indicated by “e”.

Another process rule similarly includes the circuit unit C′ corresponding to the circuit unit C, and the process rule specifies that the circuit unit C in the first layout is mapped to a form of the circuit unit C′ shown in FIG. 8. A connection mode identifier “m” is specified in the process rule. In the connection mode indicated by “m”, the via is placed near an endpoint of the metal wire, and the via is connected to the endpoint of the metal wire and the circuit unit C′ respectively. In this case, the via tv1 is generated near a position above tw1, tw2 is generated in the layer M2 to connect tw1 to tv1, and tw3 is generated in the layer M1 to connect the port ZN on cw1 inside the circuit unit C′ to tv1. As shown in FIG. 9(b), a second layout is generated based on the featureless layout with the connection mode indicated by “m”.

In the process rule, there may be a case in which the annotation of the port of the circuit unit remains the same but a shape of the port is changed. In a case that the annotation of the port remains the same but a shape of the port is changed, it is required to add a parameter corresponding to the shape of the port to the parameters corresponding to the circuit unit. It may also be a case that the annotation of the port of the circuit unit C is different from the annotation of the port of the circuit unit C′. In a case that the annotations of the ports are different, the name of the circuit unit may be inputted to acquire a corresponding list and a correspondence relationship is determined through the list, as shown in FIG. 10. In addition, there may be a case that both the shape and the annotation of the port are changed, and the above two solutions are combined to solve the problem that both the shape and the annotation of the port are changed.

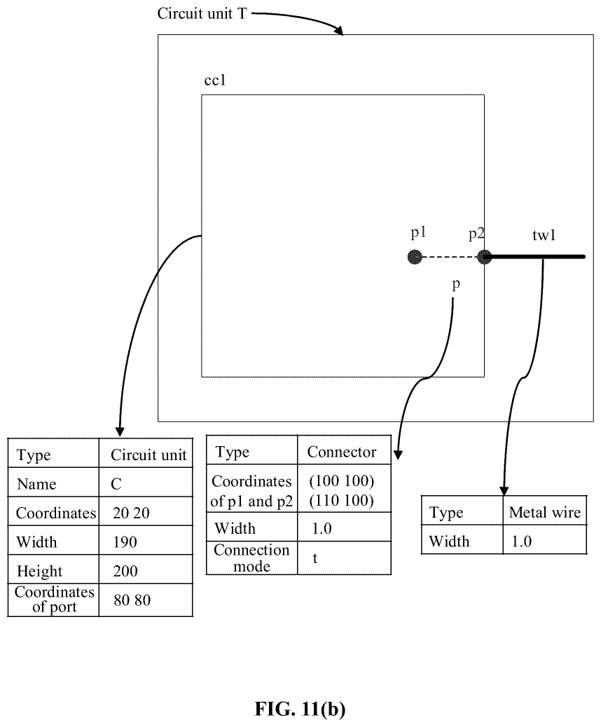

As an example, a first layout is provided as shown in FIG. 11(a) for illustration. Components in the first layout shown in FIG. 11(a) are all located in a same layer of the integrated circuit layout. A circuit unit C in FIG. 11(a) is the same as the circuit unit C in FIG. 6(a). A circuit unit T in FIG. 11(a) is a to-be-processed region. The shown layout includes the circuit unit C and a wire tw1 located in the layer M1, cw1 and cw2 are line components inside the circuit unit C in the layout. cw1 inside the circuit unit C is connected to tw1.

FIG. 11(b) is a featureless layout corresponding to the integrated circuit layout in FIG. 11(a). In a table to which cc1 points, content corresponding to “type” indicates that a component type of cc1 is a circuit unit, content corresponding to “name” indicates that a name of cc1 is C, and content corresponding to “coordinates” indicate that coordinates of top point of cc1 are (20, 20). Where, the top point is a point at a top left corner of cc1. Apparently, the top point may be another point in other cases. Content corresponding to “width” indicates that a width of cc1 is 190 μm, content corresponding to “height” indicates that a height of cc1 is 200 μm, and content corresponding to “coordinates of port” indicates that coordinates of the port ZN of cc1 are (80,80). Since the connection is between components located in a same layer, there is no via. Parameters to which “p” points include coordinates of a point p1 and coordinates of a point p2. The coordinates of p1 are (100, 100), and the coordinates of p2 are (110, 100). Content corresponding to “type” indicates that a component type of “p” is “connector”, and content corresponding to “width” indicates that a width of the metal wire tw1 is 1.0 μm. Content corresponding to “connection mode” is “t”, which indicates that the connection is between components in a same layer without vias.

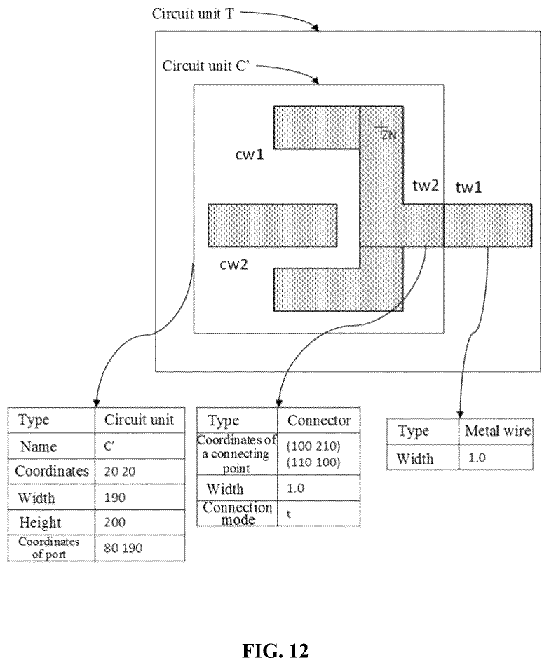

The process rule specifies that the circuit unit C is mapped to the circuit unit C′ as shown in FIG. 8. The coordinates of the port ZN in the circuit unit C′ are changed from (80, 80) to (80, 190). In generation of the second layout, the coordinates of p1 are adjusted from (100, 100) to (100, 210), and the second layout as shown in FIG. 12 is obtained based on the adjusted parameters.

By using the featureless layout generated with the method according to the present disclosure, component mapping information in the process rule can be acquired in the scenarios of process optimization and process migration. In generation of the second layout, the target components are re-optimized and generated, which improves the efficiency compared with the conventional technology. The connection mode identifier is acquired in the process rule, and the connection mode identifier is changed to change a connection mode, which is simpler and has better usability compared with the conventional technology.

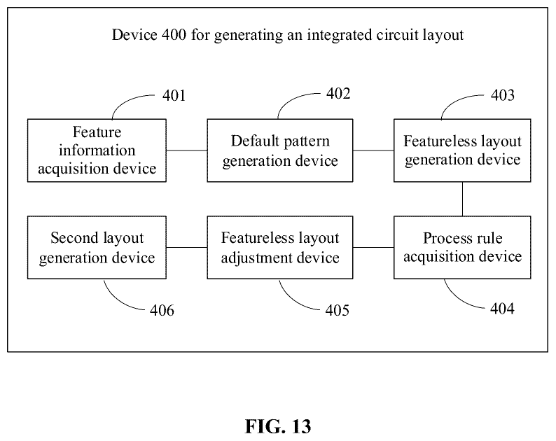

A device 400 for generating an integrated circuit layout as shown in FIG. 13 is further provided according to the present disclosure. The device includes a feature information acquisition device 401, a default pattern generation device 402, a featureless layout generation device 403, a process rule acquisition device 404, a featureless layout adjustment device 405, and a second layout generation device 406.

The feature information acquisition device 401 is configured to acquire feature information corresponding to multiple components in a first layout and determine the multiple of components as target components respectively. Where, the feature information at least includes a type, a size, a layer, and a position of each component.

The default pattern generation device 402 is configured to generate default patterns corresponding to the target components based on types of the target components.

The featureless layout generation device 403 is configured to generate a featureless layout by using the feature information corresponding to the target components as parameter information of the default patterns.

The process rule acquisition device 404 is configured to acquire a process rule.

The featureless layout adjustment device 405 is configured to adjust the parameter information of the default patterns based on the process rule to obtain an adjusted featureless layout.

The second layout generation device 406 is configured to obtain a second layout based on the adjusted featureless layout and the process rule.

A device for generating an integrated circuit layout is further provided according to the present disclosure. The device includes a memory having a computer program stored thereon; and a processor; where the processor, when executing the computer program, is configured to implement the above method for generating an integrated circuit layout. The details of which will be not repeated here.

A non-transitory computer readable storage medium is further provided according to the present disclosure. The non-transitory computer readable storage medium stores a computer program thereon, where the computer program, when executed by a processor, implements the above method for generating an integrated circuit layout. The details of which will be not repeated here.

Based on the above description, the present disclosure has the following beneficial effects compared with the conventional technology.

A method for generating an integrated circuit layout is provided according to the present disclosure. The default patterns in the featureless layout generated with the method according to the present disclosure have the attribute parameters of the components in the first layout, so that the featureless layout can accurately represent the components in the first layout. In the present disclosure, a geometric line is generated to correspond to a metal wire, a geometric point is generated to correspond to a via, and a geometric rectangle is generated to correspond to a circuit unit. In the present disclosure, geometric patterns conforming to the features of the components in the integrated circuit are generated to correspond to the components, and the generated featureless layout has excellent usability. In the present disclosure, the relative position information corresponding to the target components are used as the relative position information of the default patterns. The featureless layout generated in this way has the relative positional relationship of the target components in the first layout, which can better represent the components in the first layout. The featureless layout generated with the method according to the present disclosure can adapt to a process variation well and has strong extensibility.

The featureless layout generated with the method according to the present disclosure can be used for process optimization or process migration. The parameters of the default patterns in the featureless layout can be adjusted by using the process rule, and the second layout can be generated based on the adjusted parameters. Compared with the conventional technology, by using the featureless layout generated with the method according to the present disclosure, process optimization or process migration can be more efficient.

It should be noted that the embodiments in this specification are described in a progressive manner, each of the embodiments emphasizes the differences between the embodiment and other embodiments, and the same or similar parts among the embodiments may be referred to each other. Since the device embodiments are basically similar to the method embodiments, the description of the device embodiments is relatively simple, and for relevant matters, reference is to the description of the method embodiments. The device embodiments described above are merely illustrative. Units described as separate components may be or may not be physically separated. Components shown as units may be or may not be physical units, that is, the components may be located in a same place or may be distributed in multiple networked units. Part or all of the devices may be selected according to actual needs to achieve the purpose of the solutions of the embodiments. Those skilled in the art may understand and implement the present disclosure without any creative effort.

The above embodiments are only some specific embodiments of the present disclosure, and the protection scope of the present disclosure is not limited thereto. Any variations or replacements that can be easily conceived by those skilled in the art within the technical scope disclosed in the present disclosure should fall within the protection scope of the present disclosure. Therefore, the protection scope of the present disclosure is defined by the claims.

1. A method for generating an integrated circuit layout, comprising:
acquiring feature information corresponding to a plurality of components in a first layout, and determining the plurality of components as target components respectively, wherein the feature information at least comprises a type, a size, a layer, and a position of each component;
generating, based on types of the target components, default patterns corresponding to the target components;
generating a featureless layout by using the feature information corresponding to the target components as parameter information of the default patterns;
acquiring a process rule;
adjusting, based on the process rule, the parameter information of the default patterns, to obtain an adjusted featureless layout; and
obtaining, based on the adjusted featureless layout and the process rule, a second layout.

2. The method according to claim 1, wherein the process of generating, based on the types of the target components, the default patterns corresponding to the target components comprises:
in a case that the target component is a metal wire, generating a geometric line corresponding to the metal wire;
in a case that the target component is a circuit unit, generating a geometric rectangle corresponding to the circuit unit; and
in a case that the target component is a via, generating a geometric point corresponding to the via.

3. The method according to claim 2, wherein in a case that the target component is the circuit unit, the method further comprises:
generating a point corresponding to a port of the circuit unit in the featureless layout; and
generating a geometric dashed line in the featureless layout, wherein the geometric dashed line corresponds to a connecting line between the port of the circuit unit and a metal wire outside the circuit unit.

4. The method according to claim 1, wherein the process rule comprises a first process rule, a second process rule and an optimization rule.

5. The method according to claim 4, wherein the method further comprises:
acquiring a ratio of a minimum size of each target component in the first process rule to an actual size of an actual component corresponding to each target component in the first layout; and
obtaining the second layout, based on the ratio, the adjusted featureless layout and the second process rule.

6. The method according to claim 4, wherein the method further comprises:
acquiring a ratio of the size of each target component to a size of an adjacent component in the first process rule; and
obtaining the second layout, based on the ratio, the adjusted featureless layout and the second process rule.

7. The method according to claim 4, wherein the optimization rule comprises: mapping information of a circuit unit.

8. The method according to claim 3, wherein the feature information further comprises a connection mode identifier, which is used for identifying a connection mode between the target components; and
the process of adjusting, based on the process rule, the parameter information of the default patterns, to obtain an adjusted featureless layout comprises:
adjusting, based on the connection mode identifier between target components in the process rule, a connection mode between default patterns in the featureless layout to obtain the adjusted featureless layout.

9. The method according to claim 7, wherein the method further comprises:
based on the mapping information of the circuit unit, acquiring, in the process rule, components corresponding to the target components;
in generation of the second layout, mapping components in the second layout generated based on the default patterns corresponding to the target components as the components corresponding to the target components; and
determining, based on the parameter information of the default patterns in the adjusted featureless layout, feature information of the components corresponding to the target components in the second layout.

10. A device for generating an integrated circuit layout, comprising:
a feature information acquisition device, configured to acquire feature information corresponding to a plurality of components in a first layout and determine the plurality of components as target components respectively, wherein the feature information at least comprises a type, a size, a layer, and a position of each component;
a default pattern generation device, configured to generate default patterns corresponding to the target components based on types of the target components;
a featureless layout generation device, configured to generate a featureless layout by using the feature information corresponding to the target components as parameter information of the default patterns;
a process rule acquisition device, configured to acquire a process rule;
a featureless layout adjustment device, configured to adjust the parameter information of the default patterns based on the process rule to obtain an adjusted featureless layout; and
a second layout generation device, configured to obtain a second layout based on the adjusted featureless layout and the process rule.

11. A device for generating an integrated circuit layout, comprising:
a memory having a computer program stored thereon; and
a processor; wherein the processor, when executing the computer program, is configured to:
acquire feature information corresponding to a plurality of components in a first layout, and determine the plurality of components as target components respectively, wherein the feature information at least comprises a type, a size, a layer, and a position of each component;
generate, based on types of the target components, default patterns corresponding to the target components;
generate a featureless layout by using the feature information corresponding to the target components as parameter information of the default patterns;
acquire a process rule;
adjust, based on the process rule, the parameter information of the default patterns, to obtain an adjusted featureless layout; and
obtain, based on the adjusted featureless layout and the process rule, a second layout.

12. The device according to claim 11, wherein the processor is further configured to:
in a case that the target component is a metal wire, generate a geometric line corresponding to the metal wire;
in a case that the target component is a circuit unit, generate a geometric rectangle corresponding to the circuit unit; and
in a case that the target component is a via, generate a geometric point corresponding to the via.

13. The device according to claim 12, wherein in a case that the target component is the circuit unit, the processor is further configured to:
generate a point corresponding to a port of the circuit unit in the featureless layout; and
generate a geometric dashed line in the featureless layout, wherein the geometric dashed line corresponds to a connecting line between the port of the circuit unit and a metal wire outside the circuit unit.

14. The device according to claim 11, wherein the process rule comprises a first process rule, a second process rule and an optimization rule.

15. The device according to claim 14, wherein the processor is further configured to:
acquire a ratio of a minimum size of each target component in the first process rule to an actual size of an actual component corresponding to each target component in the first layout; and
obtain the second layout, based on the ratio, the adjusted featureless layout and the second process rule.

16. The device according to claim 14, wherein the processor is further configured to:
acquire a ratio of the size of each target component to a size of an adjacent component in the first process rule; and
obtain the second layout, based on the ratio, the adjusted featureless layout and the second process rule.

17. The device according to claim 14, wherein the optimization rule comprises: mapping information of a circuit unit.

18. The device according to claim 13, wherein the feature information further comprises a connection mode identifier, which is used for identifying a connection mode between the target components; and
the processor is further configured to:
adjust, based on the connection mode identifier between target components in the process rule, a connection mode between default patterns in the featureless layout to obtain the adjusted featureless layout.

19. The device according to claim 17, wherein the processor is further configured to:
based on the mapping information of the circuit unit, acquire, in the process rule, components corresponding to the target components;
in generation of the second layout, map components in the second layout generated based on the default patterns corresponding to the target components as the components corresponding to the target components; and
determine, based on the parameter information of the default patterns in the adjusted featureless layout, feature information of the components corresponding to the target components in the second layout.

20. A non-transitory computer readable storage medium storing a computer program thereon, wherein the computer program, when executed by a processor, implements the method for generating the integrated circuit layout according to claim 1.
